(19) United States
(12) Patent Application Publication
(10) Pub. No.: US 2024/0204057 A1
(43) Pub. Date: Jun. 20, 2024

(54) METHODS FOR FORMING SEMICONDUCTOR STACKED STRUCTURES ON A SUBSTRATE AND RELATED SEMICONDUCTOR STRUCTURES

(71) Applicant: ASM IP Holding B.V., Almere (NL)

(72) Inventors: Amir Kajbafvala, Chandler, AZ (US); Yanfu Lu, Phoenix, AZ (US); Caleb Miskin, Mesa, AZ (US)

(21) Appl. No.: 18/540,230

(22) Filed: Dec. 14, 2023

Related U.S. Application Data
(60) Provisional application No. 63/387,684, filed on Dec. 15, 2022.

(51) Int. Cl. H01L 29/161; H01L 21/02; H01L 21/66; H01L 29/06; H01L 29/423; H01L 29/66; H01L 29/775; H01L 29/786

(52) U.S. Cl. CPC H01L 29/161; H01L 21/02532; H01L 22/12; H01L 29/0673; H01L 29/42392; H01L 29/66439; H01L 29/775; H01L 29/78696

(57) ABSTRACT

Methods for forming semiconductor stacked structures are disclosed. The methods may include, seating a substrate within a chamber body, and regulating a temperature profile across an upper surface of the substrate during each individual step of a sequential deposition process. Semiconductor stacked structures including two or more bilayers of SiGe/Si with intervening interface layers are also disclosed.

### CROSS-REFERENCE TO RELATED APPLICATION(S)

This application claims the benefit of U.S. Provisional Application 63/387,684 filed on Dec. 15, 2022, the entire contents of which are incorporated herein by reference.

### FIELD OF INVENTION

The present disclosure relates generally to the field of semiconductor processing methods and systems, and to the field of device and integrated circuit manufacture. In particular, the present the disclosure generally relates to methods for controlling the temperature profile across an upper surface of a substrate during the deposition of semiconductor structures.

### BACKGROUND OF THE DISCLOSURE

Recently, three-dimensional devices, such as gate-all-around (GAA), and nanowire devices, have been developed in an effort to form high-performance devices with increased device density, improved performance, and/or at lower costs. Further next generation three-dimensional devices are also being developed and include, nanosheet devices, forksheet devices, and complementary FET (CFET) devices.

During the formation of such three-dimensional devices, a semiconductor stacked structure composed of alternating layers of silicon germanium (SiGe layers) and silicon (Si layers) can be formed by sequentially depositing the SiGe layers and the Si layers on a surface of a substrate. Portions of these layers can be subsequently etched to form (e.g., silicon) wires, sheets, etc., that can form the channel regions of these advance three-dimensional devices.

For many devices having Si layers epitaxially formed overlying SiGe layers, it is desirable to have a sharp, abrupt, and consistent interface layer between a SiGe layer and a Si layer epitaxially formed thereon. Unfortunately, germanium (Ge) on the surface of the SiGe layer is energetically more favorable than silicon (Si) on the surface of the SiGe layer. Consequently, if the surface of the SiGe layer is not correctly passivated prior to the subsequent Si layer deposition, the germanium (Ge) can segregate, resulting in the formation of an undesirably large interface layer, also referred to as the transition region or interface region. Then, as a first monoatomic layer of Si is grown, germanium (Ge) can segregate into the overlaying silicon (Si) layer. This mechanism can be repeated during the growth of the Si layer, creating interface layers with an undesirable thicknesses of greater than a few tens of angstroms.

In addition to surface passivation issues causing poor interface layers, inadequate control of the surface temperature of the substrate during deposition of semiconductor stacked structures can be an additional contributor to poor transitions from the SiGe layers to the overlaying Si layers. Undesirable temperature gradients and/or temperature differentials across the deposition surface of a substrate during the deposition of a semiconductor stacked structure can result in poor layer transitions, as well as undesirable variations in both layer composition and thickness.

Accordingly, improved methods for epitaxially forming stacked structures comprising SiGe layers and Si layers, are desired.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In particular, the present disclosure described methods for forming a semiconductor structure, comprising: seating a substrate within a chamber body, and regulating a temperature profile across an upper surface of the substrate during each individual process step of a sequential deposition process by employing a feedback control procedure comprising, acquiring at least two independent sets of optical temperature measurements from at least two separate areas on the upper surface of the substrate, and throttling the heating of the substrate according to a temperature differential or a temperature gradient across the upper surface of the substrate as determined by the at least two independent sets of optical temperature measurements. The methods of the disclosure further comprise, depositing a semiconductor stacked structure on the substrate by performing two or more sequences of a sequential deposition process, wherein each sequence of the sequential deposition process comprises at least the process steps of, introducing a first precursor gas into the chamber body to epitaxially deposit a first layer comprising silicon and germanium on the substrate, and subsequently introducing a transition gas into the chamber body to passivate an exposed surface of the first layer, and subsequently introducing a second precursor gas into the chamber body to epitaxially deposit a second layer comprising silicon over the first layer.

In some embodiments, throttling the heating of the substrate further comprises, regulating power supplied to a upper heater element array disposed above the chamber body based on the at least two independent sets of optical temperature measurements.

In some embodiments, the at least two independent sets of optical temperature measurements comprise a first set of optical temperature measurements (T1) acquired from a first acquisition area of the upper surface of substrate by a first pyrometer supported above the upper heater elements array, and a second set of optical temperature measurements (T2) acquired from a second acquisition area of the upper surface of the substrate by a second pyrometer supported above the upper heater element, wherein the first acquisition area and the second acquisition area are separated from one another.

In some embodiments, the first pyrometer is arranged along a first optical axis and the second pyrometer is arranged along a second optical axis, the second optical axis being radially outward of the first optical axis.

In some embodiments, the first layer comprises a silicon germanium (Si₁₋ₓGeₓ) layer, wherein the germanium content (x) is greater than zero and less than 0.5, and the germanium content (x) non-uniformity is less than 0.2%.

In some embodiments, introducing a transition gas into the chamber body further comprises, stopping the flow of any germanium containing gas into the chamber body, and subsequently introducing the transition gas into the chamber body, wherein the transition gas comprises a silicon containing gas, and at least one of a silicon halide containing gas, and hydrochloric acid (HCl) vapor.

In some embodiments, introducing the transition gas into the chamber body further comprises, depositing a silicon capping layer directly on the first layer.

In some embodiments, an interface layer is disposed between the first layer and the second layer, the interface layer having an average thickness of less than 10 Angstroms.

The present disclosure also describes methods for forming a semiconductor stacked structure on a surface of a substrate, the method comprising, seating a substrate on a substrate support disposed in a chamber body, the chamber body having an upper wall and a lower wall, and heating the substrate to a deposition temperature employing an upper heater element array supported above the upper wall of the chamber body and a lower heater element array supported below the lower wall of the chamber body. The methods of the present disclosure can further comprise, providing a controller in communication with at least the upper heater element array, wherein the controller throttles power to at least the upper heater element array according to a set of optical temperature measurements communicated to the controller from at least a first pyrometer and a second pyrometer, the at least first pyrometer and the second pyrometer being supported above the upper heater element array and being optically coupled to the substrate surface over at least a first acquisition area and a second acquisition area, wherein the second acquisition area is radially distal from the first acquisition area. The methods of the present disclosure may further comprise, depositing two or more silicon germanium (Si₁₋ₓGeₓ)/silicon (Si) bilayers on the substrate by a sequential deposition process, wherein a unit sequence of the sequential deposition process comprises at least the process steps of; epitaxially deposit a silicon germanium (Si₁₋ₓGeₓ) layer over the substrate, introducing a transition gas comprising a chlorine containing gas into the reaction chamber for set time period, and epitaxially depositing a silicon (Si) layer over the silicon germanium (Si₁₋ₓGeₓ) layer; and forming an interface layer disposed between the silicon germanium (Si₁₋ₓGeₓ) layer and the silicon (Si) layer, wherein the interface layer has an average thickness of less than 10 Angstroms.

In some embodiments, introducing the transition gas further comprises, stopping the flow of any germanium containing precursor into the chamber body prior to introducing the transition gas, the transition gas comprising, silane (SiH4), and at least one of dichlorosilane (DCS), and hydrochloric acid (HCl) vapor.

In some embodiments, introducing the transition gas further comprises, reducing the thickness of the interface layer with increasing flow time of the transition gas.

In some embodiments, the transition gas is introduced into the chamber body for a time period of less than 100 seconds.

In some embodiments, the interface layer further comprises a silicon capping (Si) layer deposited directly on the surface of the silicon germanium (Si₁₋ₓGeₓ) layer, wherein the silicon (Si) capping layer prevents segregation of germanium (Ge) from the silicon germanium (Si₁₋ₓGeₓ) layer into the adjacent silicon (Si) layer.

In some embodiments, the upper wall of the chamber extends longitudinally between an injection end and a longitudinally opposite exhaust end, and the lower wall is below and parallel relative to the upper wall.

In some embodiments, the reaction chamber comprises an arcuate, or dome-like shape.

Further embodiments of the present disclosure also include semiconductor structure comprising, two or more bilayers, each bilayer comprising a silicon germanium (Si₁₋ₓGeₓ) layer, an overlaying silicon (Si) layer, and an interface layer disposed directly between the silicon germanium (Si₁₋ₓGeₓ) layer and silicon (Si) layer, formed by methods of present disclosure.

Additional embodiments of the present disclosure include further semiconductor structures comprising, a substrate, two or more bilayers disposed directly one on top of one another to form a semiconductor stacked structure, wherein a single bilayer comprises, a silicon germanium (Si₁₋ₓGeₓ) layer, a silicon (Si) layer disposed over the silicon germanium (Si₁₋ₓGeₓ) layer, and an interface layer disposed directly between silicon germanium (Si₁₋ₓGeₓ) layer and the silicon (Si) layer, wherein each interface layer within the semiconductor stacked structure has an average layer thickness of less than 10 Angstroms.

In some embodiments, each silicon germanium (Si₁₋ₓGeₓ) layer within the semiconductor stacked structure has a germanium content (x) greater than zero and less than 0.5 and a germanium content (x) non-uniformity of less than 0.2%.

In some embodiment, each silicon layer within the semiconductor stacked structure has a thickness non-uniformity of less than 1 Angstrom.

In some embodiments, a partially fabricated semiconductor device structure comprising the structures of the present disclosure are described, wherein the partially fabricated semiconductor device structures may comprise a partially fabricated gate-all-around (GAA) transistor device structure, a partially fabricated nanosheet device structure, a partially fabricated forksheet device structure, and a partially fabricated complementary FET (CFET) device structure.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrate an exemplary method in accordance with the embodiments of the disclosure;

FIG. 2 illustrates a schematic diagram of a reaction chamber arrangement including in particular two pyrometers and an upper heater element array in accordance with the embodiments of the disclosure;

FIG. 3 illustrates an exemplary simplified schematic diagram of a temperature control system for feedback controlling the temperature profile across an upper surface of a substrate during a sequential deposition process in accordance with the embodiments of the disclosure;

FIG. 4 illustrates an exemplary method which includes a feedback controlled substrate surface temperature procedure employed during each process step of a sequential deposition process in accordance with the embodiments of the disclosure;

FIG. 5 graphically illustrates exemplary data demonstrating a relationship between transition gas flow time and a corresponding thickness of the interface layer formed between a SiGe layer and an overlaying Si layer;

FIGS. 6-7 illustrate cross-sectional schematic diagrams of exemplary structures formed in accordance with the embodiments of the disclosure; and

FIG. 8 graphically illustrates exemplary data demonstrating high quality, low average thickness interface layers obtained across an entire SiGe/Si semiconductor stacked structure in accordance with the embodiments of the disclosure; and

FIGS. 9-12 illustrate exemplary simplified cross-sectional diagrams of three-dimensional advance device structures obtained in accordance with the embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices, and apparatus provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gases. Exemplary seal gasses include noble gasses, nitrogen, and the like. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The substrate may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e. ceramic fibers or polymer fibers). Continuous substrates may also comprise carriers or sheets upon which non-continuous substrates are mounted.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate and/or may be or may become embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices. A film or layer may be selectively grown on some parts of a substrate, and not on others.

The term “deposition process” as used herein can refer to the introduction of precursors (and/or reactants) into a reaction chamber to deposit a layer over a substrate. “sequential deposition processes” are examples of “deposition processes”.

The term “epitaxial layer” as used herein can refer to a substantially single crystalline layer upon an underlying substantially single crystalline substrate or layer.

The term “chemical vapor deposition” as used herein can refer to any process wherein a substrate is exposed to one or more volatile precursors, which react and/or decompose on a substrate surface to produce a desired deposition.

The term “silicon germanium” as used herein can refer to a semiconductor material comprising silicon and germanium and can be represented as Si₁₋ₓGeₓ wherein 1≥x≥0, or 0.8≥x≥0.1, or 0.6≥x≥0.2, or materials comprising silicon and germanium having compositions as set forth herein.

The term “sequential deposition process” can refer to the deposition of repeated units of semiconductor layers, such as, for example, units of SiGe/Si bilayers. For example, a single deposition sequence can deposit a layer structure (e.g., a bilayer structure) and the deposition sequence can be repeated two or more times to repeatedly deposit multiple layer structures (e.g., multiple bilayers) one on top of one another thereby forming a semiconductor stacked structure. Sequential deposition processes can be performed employing deposition techniques such as chemical vapor deposition, plasma-enhanced chemical vapor deposition, atomic layer deposition, and plasma-enhanced atomic layer deposition.

The terms “interface layer thickness” and “interface thickness” can refer to the thickness of the region between two adjacent semiconductor layers and particular the interface thickness of the interface region between two adjacent semiconductor layers comprising differing compositions. For example, the interface thickness between a silicon (Si) layer and an adjacent silicon germanium (Si₁₋ₓGeₓ) layer, wherein (x)=0.30, may be defined as the thickness of the region disposed between the two adjacent semiconductor layers wherein the composition of the interface region does not comprise that of silicon (Si) or that of (Si₁₋ₓGeₓ) wherein x=0.30, but rather is a composite of the two adjoining semiconductor compositions, since the interface between the two adjoining semiconductor materials may not be atomically abrupt. As described herein in relation to the embodiments of the disclosure, the interface thickness between two adjacent semiconductor layers of differing composition may be determined utilizing a number of analytic methods, including, but not limited to, spectroscopic ellipsometry (SE), secondary ion mass spectrometry (SIMS), transmission electron microscopy (TEM), and x-ray reflectometry (XRR).

As used herein, a “precursor” includes a gas, gases, or a material or materials that can become gaseous and that can be represented by a chemical formula that includes an element which may be incorporated during a deposition process as described herein.

As used herein, a “semiconductor stacked structure” can refer to two or more unit structures (e.g., bilayers of SiGe/Si) overlaying one another over a surface of a substrate or within a substrate. Full devices structures or partial device structures (i.e., partially fabricated device structures) can include semiconductor stacked structures.

A number of example materials are given throughout the embodiments of the current disclosure, it should be noted that the chemical formulas given for each of the example materials should not be construed as limiting and that the non-limiting example materials given should not be limited by a given example stoichiometry.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

The present disclosure includes methods for forming semiconductor stacked structures. In some embodiments, the semiconductor stacked structures can comprise repeating bilayers of silicon germanium and silicon (Si₁₋ₓGeₓ/Si) epitaxially deposited over the surface of a substrate. The methods disclosed facilitate the formation of such semiconductor stacked structures including Si₁₋ₓGeₓ/Si bilayers with abrupt, sharp, interface layers, the interface being disposed between the silicon germanium layer and the silicon layer. The high quality, sharp interface layers of the present disclosure can be formed in part due to the use of full temperature feedback control over the entire upper surface of the substrate during the sequential deposition of the semiconductor stacked structure. In addition, the present disclosure describes novel deposition methods for depositing the semiconductor stacked structure, e.g., by depositing silicon germanium/silicon bilayers that include high quality, abrupt, sharp, interface layers. The present disclosure also includes structures formed according to the methods described herein.

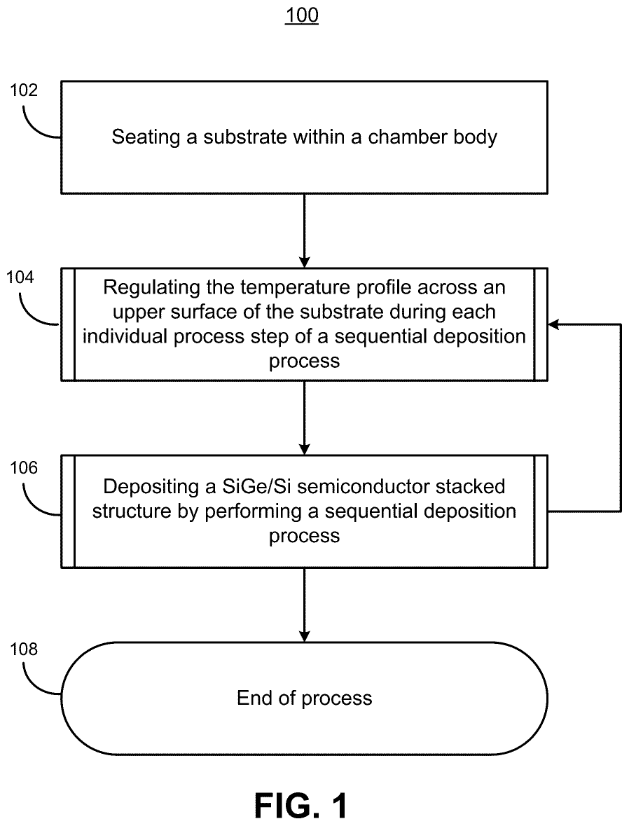

Therefore, an exemplary method 100 for forming semiconductor stacked structures on the surface of a substrate according to the embodiments of the present disclosure is illustrated with reference FIG. 1. Briefly, method 100 can include the process steps of, seating a substrate within a chamber body (step 102), regulating the temperature profile across an upper surface of a substrate during each individual process step of a sequential deposition process (step 104), and depositing a SiGe/Si semiconductor stacked structure by performing a sequential deposition process (step 106). The exemplary process 100 can subsequently conclude as illustrated by end step 108.

In more detail, the exemplary method 100 includes process step 102 which in some embodiments comprises, seating a substrate into a chamber body of a deposition apparatus, the deposition apparatus can include a reaction chamber arrangement including an upper heater element array supported above the reaction chamber.

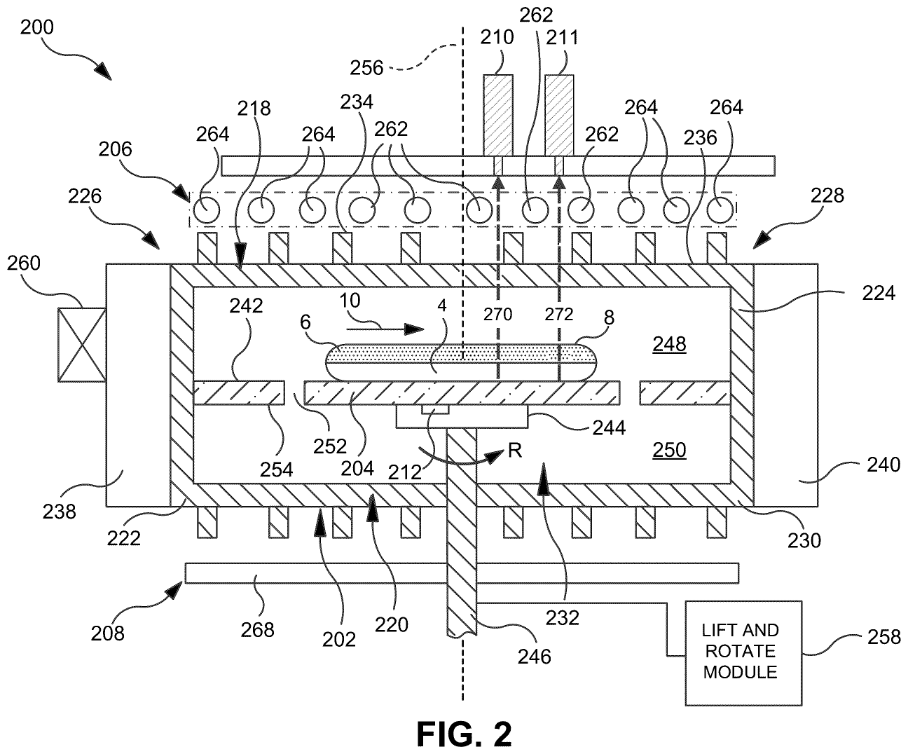

FIG. 2 illustrates an exemplary deposition apparatus and particular a reaction chamber arrangement 200 configured for performing the methods of the present disclosure.

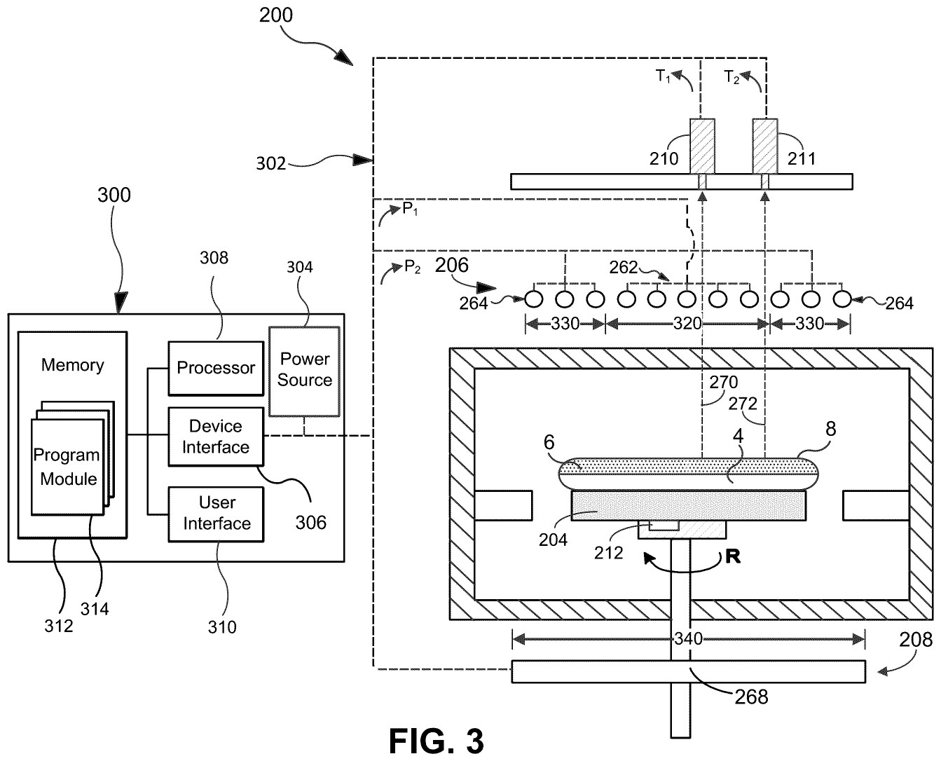

The reaction chamber arrangement 200 includes a chamber body 202 and a substrate support 204. The reaction chamber arrangement 200 can also include an upper heater element array 206 and a lower heater element array 208. The reaction chamber arrangement 200 can further include a first pyrometer 210, a second pyrometer 211, a thermocouple 212, a controller 300 (shown in FIG. 3), and a link 302 providing communication and/or power between the reaction chamber arrangement 200 and the controller 300 (FIG. 3). Although a specific arrangement is shown and described herein it is to be understood and appreciated that the reaction chamber arrangement 200 (FIG. 2) may include other elements and/or omit elements shown and described herein and remain within the scope of the present disclosure.

The chamber body 202 is configured to flow the precursor 10 across and contact the substrate 4. The chamber body 202 has an upper wall 218, a lower wall 220, a first sidewall 222, and a second sidewall 224. The upper wall 218 extends longitudinally between an injection end 226 and a longitudinally opposite exhaust end 228 of the chamber body 202, and is supported horizontally relative to gravity, and is formed from a transmissive material 230. The lower wall 220 is below and parallel relative to the upper wall 218 of the chamber body 202, is spaced apart from the upper wall 218 by an interior 232 of the chamber body 202, and is also formed from the transmissive material 230. The first sidewall 222 longitudinally spans the injection end 226 and the exhaust end 228 of the chamber body 202, extends vertically between the upper wall 218 and the lower wall 220 of the chamber body 202, and is formed from the transmissive material 230. The second sidewall 224 is parallel to the first sidewall 222, and is laterally opposite and spaced apart from the first sidewall 222 by the interior 232 of the chamber body 202, and is further formed from the transmissive material 230. In certain examples, the transmissive material 230 may include a ceramic material such as sapphire or quartz.

In accordance with certain examples, the chamber body 202 may include a plurality of external ribs 234. The plurality of external ribs 234 may extend laterally about an exterior 236 of the chamber body 202 and be longitudinally spaced between the injection end 226 and the exhaust end 228 of the chamber body 202. In certain examples, the one or more of the walls 218-222 may be substantially planar. In accordance with certain examples, one or more of the walls 218-222 may be arcuate or dome-like in shape. It is also contemplated that, in accordance with certain examples, the chamber body 202 may include no ribs.

An injection flange 238 and an exhaust flange 240 may be connected to the injection end 226 and the exhaust end 228, respectively, of the chamber body 202. The injection flange 238 may fluidly couple a precursor delivery apparatus (now shown) to the interior 232 of the chamber body 202 and be configured to provide one or more precursor to the interior 232 of the chamber body 202. The exhaust flange 240 may fluidly couple the interior 232 of the chamber body 202 to an exhaust apparatus (not shown). The exhaust flange 240 may be configured to remove any residual precursor and/or reaction byproducts from the reaction chamber arrangement 200 during deposition of the material layer(s) onto the substrate 4. In this respect the chamber body 202 may be have a cold wall, cross-flow reactor configuration, although alternative configuration can be employed.

A divider 242, a support member 244, and a shaft member 246 may be arranged within the interior 232 of the chamber body 202. The divider 242 may be fixed within the interior 232 of the chamber body 202 and divide the interior 232 of the chamber body 202 into an upper chamber 248 and a lower chamber 250. The divider 242 may further define an aperture 252 therethrough, the aperture 252 fluidly coupling the upper chamber 248 of the chamber body 202 to the lower chamber 250 of the chamber body 202. The divider 242 may be formed from an opaque material 254. The opaque material 254 may include silicon carbide.

The substrate support 204 may be configured to seat thereon the substrate 4 and can be supported at least partially within the aperture 252 for rotation R about a rotation axis 256. The substrate support 204 may seat the substrate 4 such that a radially-outer peripheral of the substrate 4 abuts the substrate support 204 while a radially-inner central portion of the substrate 4 is spaced apart from the substrate support 204. The support member 244 may be arranged below the substrate support 204 and along the rotational axis 256. The support member 244 may be further arranged within the lower chamber 250 of the chamber body 202, and fixed in rotation relative to the substrate support 204 about the rotational axis 256 for rotation with the substrate support 204. The substrate support 204 may be formed from an opaque material, such as the opaque material 230 or a graphite, or graphite coated material. The support member 244 may be formed from a transmissive material, such as the transmissive material 230.

The shaft member 246 may be arranged along the rotational axis 256 and fixed in rotation relative to the support member 244 about the rotational axis 256. The shaft member 246 may also extend through the lower chamber 250 of the chamber body 202 and through lower wall 220 of chamber body 202. The shaft member 246 may further operably connect a lift and rotate module 258 to the substrate support 204, the lift and rotate module 258 in turn configured to rotate R the substrate support 204 and the substrate 4 about the rotational axis 256 during deposition of one or more material layers 6 onto an upper surface 8 of the substrate 4. The lift and rotate module 258 may further cooperate with a gate valve 260 and a lift pin arrangement (not shown) to seat and unseat the substrate 4 from the substrate support 204, such as through a substrate handling robot arranged within a cluster-type platform in selective communication with the interior 232 of the chamber body 202 through the gate valve 260. In certain examples the shaft member 246 may be formed from a transmissive material, such as the transmissive material 230.

The upper heater element array 206 is configured to heat the substrate 4, and/or the material layer 6, and the upper surface of substrate 8 during deposition of material layer(s) onto the substrate 4 by radiantly communicating heat into the upper chamber 248 of the chamber body 202. In this respect the upper heater element array 206 may include the first upper heater elements 262, and the second upper heater elements 264. In some embodiments, at least one third upper heater element may be included (not shown) within the upper heater element array 206. The first upper heater elements 262 may each include a linear filament and quartz tube enclosing the linear filament and/or may include one or more bulb or lamp-type heater elements. The first upper heater elements 262 may be supported above the upper wall 218 of the chamber body 202, extend laterally between the first sidewall 222 and the second sidewall 224 of the chamber body 202, and may further overlay the substrate support 204. The second upper heater elements 264 and the optional third upper heater elements (not shown) may be similar to the first upper heater elements 262 and may additionally be longitudinally spaced apart from the first upper heater elements 262, and may further be longitudinally spaced apart from the rotational axis 256. The second upper heater elements 264 may further overlay (e.g., intersect) a peripheral edge of the substrate 4. In certain examples, the upper heater element array 206 may include eleven (11) or twelve (12) upper heater elements. Each upper heater element of the upper heater element array 206 may be longitudinally spaced apart from one another above the upper wall 218 of the chamber body 202 between the injection end 226 and the exhaust end 228 of the chamber body 202.

The lower heater element array 208 is similar to the upper heater element array 206 and is also configured to heat the substrate 4 and/or the material layer(s) 6 during deposition onto the surface 8 of the substrate 4. In this respect the lower heater element array 208 may be configured to communicate radiant heat into the lower chamber 250 of the chamber body 202 to the substrate support 204 and the divider 242. The substrate support 204 and the divider 242 may in turn heat the substrate 4 by conducting the heat through the bulk material forming the substrate support 204 and the divider 242. Radiant heat communicated into the lower chamber 250 by the lower heater element array 208 thereby being conducted to the substrate 4. The lower heater element array 208 may include a first lower heater element 268 and at least one second lower heater element (not shown).

FIG. 2 illustrates the lower heater array 208 includes an exemplary first lower heater element 268 which is similar to the first upper heater element 262 and is additionally supported below the lower wall 220 of the chamber body 202. The first lower heater element 268 further extends longitudinally between the injection end 226 and the exhaust end 228 of the chamber body 202. The first lower heater element 268 may further be substantially orthogonal relative to the first upper heater elements 262 of the upper heater element array 206. The lower heater array 208 can include at least one second lower heater element (not shown) that may be parallel to the first lower heater element 268 and laterally spaced apart from the first lower heater element 268 below the lower wall 230 of the chamber body 202. In certain examples, the first lower heater element 268 may underlie the substrate support 204. In accordance with certain examples, the at least one second lower heater element (not shown) may underlie the divider 242. It is also contemplated that, in accordance with certain examples, the lower heater element array 208 may include eleven (11) or twelve (12) lower heater elements each laterally spaced apart from one another below the lower wall 220 of the chamber body 202.

In some embodiments, a first pyrometer 210 can be configured to acquire a first set of optical temperature measurements (T₁) using electromagnetic radiation emitted by the substrate 4, the material layer(s) 6, and particularly from the upper surface of the substrate 8. In this respect the first pyrometer 210 is supported above the upper wall 218 of the chamber body 202 and is arranged along an optical axis 270 (shown in FIG. 2). More specifically, the first pyrometer 210 is supported above the upper heater element array 206 and arranged longitudinally between the injection end 226 and the exhaust end 228 of the chamber body 202 such that the optical axis 270 may extend between the first upper heater element 262 and an adjacent upper heater element. The optical axis 270 may further intersect the substrate support 204. The optical axis 270 may intersect the substrate 4 when seated on the substrate support 204, the first set of optical temperature measurements (T1) thereby acquired by the pyrometer 270 can be acquired directly from the upper surface 8 of the substrate 4 and/or the material layer(s) 6 during deposition onto the substrate 4. In certain examples, the optical axis 270 may be coaxial with the rotational axis 256. In accordance with certain examples, the first pyrometer 210 may be at least one of longitudinally offset and/or laterally offset from the rotational axis 256, e.g., radially offset from the rotation axis 256 (as illustrated in FIG. 2). As will be appreciated by those of skill in the art in view of the present disclosure, offsetting the optical axis 270 from the rotational axis 256 may facilitate packaging the first pyrometer 210 above the chamber body 202. Examples of suitable pyrometers include OR400M optical infrared pyrometers, available from the Advanced Energy Corporation of Denver, Colorado.

A second pyrometer 211 can be arranged along a second optical axis 272 and can be arranged radially outward of the first pyrometer 210 relative to the rotational axis 256. It is contemplated that the second optical axis 272 intersects the substrate support 204. More specifically, the second optical axis 272 may intersect the substrate 4 when seated on the substrate support 204, the second pyrometer 211 can thereby be configured to generate a second set of optical temperature measurements (T2) from the substrate 4 and particular from the substrate surface 8 during deposition of the material layer(s) 6 onto the substrate 4. In certain examples, the second optical axis 272 may be laterally offset from the first optical axis 270. In accordance with certain examples, the second optical axis 272 may be longitudinally offset from the first optical axis 270. It is also contemplated that the second optical axis 272 may be both laterally offset and longitudinally offset from the first optical axis 270. Therefore, the first pyrometer 210 and the second pyrometer 211 can acquire two independent sets of optical temperature measurements (T1 and T2) from two separate areas on the upper surface of the substrate. For example, the first pyrometer may be optically coupled over a first acquisition area of the upper surface of the substrate, and the second pyrometer may be optically coupled over a second acquisition area over the upper surface of the substrate, wherein the second acquisition area is radially distal from the first acquisition area.

In additional and/or alternative embodiments, the reaction chamber arrangement comprises at least two pyrometers configured for acquiring optical temperature measurements from at least two different acquisition areas on the upper surface of the substrate. Therefore, the embodiments of the disclosure can include a reaction chamber arrangement including, for example, a third pyrometer and said third pyrometer can also be employed and can be configured as described with reference to the first pyrometer 210 and the second pyrometer 211. In such embodiments, a third pyrometer may be positioned above the upper heater array 206 to enable a third optical axis that may be longitudinally and/or radially offset from both the first pyrometer 210 and the second pyrometer 211. It is also anticipated that a forth, a fifth, or even a sixth pyrometer etc., may be employed as described herein to enable profiling of the surface temperature of the substrate at multiple areas across the entire surface of the substrate.

Referring back to the exemplary method 100 (FIG. 1), once a substrate is seated within the chamber body, and particular once the substrate 4 is seated upon the substrate support 204 (FIG. 2), the exemplary method 100 (FIG. 1) may proceed by, regulating the temperature profile across an upper surface of the substrate during each individual process step of a sequential deposition process by employing a feedback control procedure (step 104). For example, regulating the upper surface temperature of the substrate during each individual process step of a sequential deposition process may comprise, acquiring at least two independent sets of optical temperature measurements from at least two separate areas on the upper surface of the substrate, and throttling the heating of the substrate according to a temperature differential or a temperature gradient across the upper surface of the substrate as determined by the at least two independent sets of optical temperature measurements.

In more detail, FIG. 3 illustrates a simplified version of the reaction chamber arrangement 200 (FIG. 2) and highlights the apparatus and methods employed in the feedback control procedure for controlling the temperature profile across the upper surface of the substrate during each individual process step of a sequential deposition process. For example, a controller 300 is connected to the upper heater element array 206 and, in some embodiments, the lower heater element array 208. In this respect the link 302 may connect the controller 300 to the upper heater element array 206 and, in some embodiments, the lower heater element array 208.

In certain examples, one or more upper silicon controlled rectifier (SCR) devices (not shown) may couple the controller 300 to the upper heater element array 206. In accordance with certain examples, a singular one of the one or more upper SCR devices couples each of the upper heater elements of the upper heater element array 206 to both the controller 300 and a power source 304. The power source 304 may be integrated within the controller 300 or alternatively may be an independent unit in communication with both the controller 300 as well as being in communication with the upper heater array 206 and the lower heater array 208 and configured to supply/regulate power to both the upper heater array element 206 and the lower heater array element 208. The controller 300 thereby can be configured to have discrete control over power applied to each of the upper heater elements of the upper heater element array 206. The lower heater element array 208 may be similarly controlled by controller 300 as described above.

It is contemplated that the controller 300 can be connected to both the first pyrometer 210 and the second pyrometer 211, for example, by the link 302. In this respect the controller 300 may operatively connect the first pyrometer 210 and the second pyrometer 211 to the upper heater element array 206. Power applied to (and thereby radiant heat output) from the upper heater element array 206 can be throttled according to the two independent sets of optical temperature measurements (T₁ and T₂) provided to the controller 300 from the first pyrometer 210 and the second pyrometer 211. For example, the first pyrometer 210 can be configured to acquire a first set of optical temperature measurements (T₁) acquired from a first acquisition area on the upper surface 8 of the substrate 4, and the second pyrometer can be configured to acquire a second set of optical temperature measurements (T₂) acquired from a second acquisition area on the upper surface 8 of the substrate 4, wherein the first acquisition area and second acquisition area are separated from one another.

In additional and/or alternative embodiments, a thermocouple 212 can be linked to the lower heater element array 208, and power applied to (and thereby radiant heat output) from the lower heater element array 208 can be throttled by a set of tactile temperature measurements provided to the controller 300 by the thermocouple 212.

As will be appreciated by those of skill in the art in view of the present disclosure, throttling heat output of the upper heater element array 206 using the first pyrometer 210 and the second pyrometer 211 (and in some embodiments throttling heat output of the lower heater element array 208 by employing thermocouple 212) may limit (or eliminate) oscillations which can otherwise cause heating of substrate 4 that could otherwise be associated with lag in arrival of heat from the lower heater element array 208 at the substrate 4 through the thermal mass of the substrate support 204.

In certain examples, the heat output of the upper heater element array 206 may be exclusively throttled using the two sets of optical temperature measurements (T₁ and T₂) provided by the first pyrometer 210 and the second pyrometer 211, and the heat output of the lower heater element array 208 may be exclusively throttled by the tactile temperature measurements provided by the thermocouple 212. It is also contemplated that hybrid throttling schemes may be employed, e.g., with weighting assignments, and remain within the scope of the present disclosure.

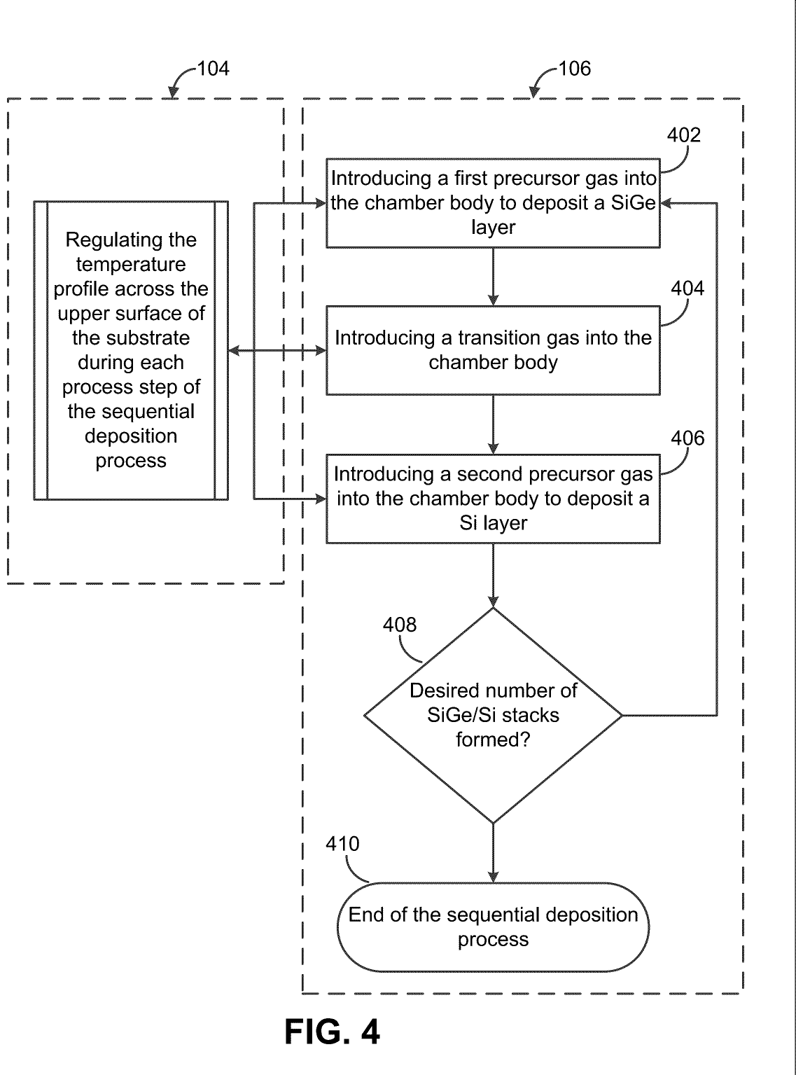

The exemplary controller 300 (FIG. 3) can include a device interface 306, a processor 308, a user interface 310, and a memory 312. The device interface 306 can connect the processor 308 to the link 302. The processor 308 is operably connected to the user interface 310 (e.g., to receive user input and/or provide user output therethrough) and is disposed in communication with the memory 312. The memory 312 includes a non-transitory machine-readable medium having a plurality of program modules 314 recorded thereon containing instructions that, when read by the processor 308, cause the processor 308 to execute certain operations. Among the operations are operations of a material layer deposition method 100 (shown in FIG. 1 and in greater detail in FIG. 4), as will be described herein. As will be appreciated by those of skill in the art in view of the present disclosure, the controller 300 may have a different arrangement in other examples and remain within the scope of the present disclosure.

In some embodiments, it is contemplated that the first upper heater elements 262 be operatively associated with the first pyrometer 210, and that the second upper heater elements 264 be operatively associated with the second pyrometer 211. In some embodiments, the lower heater element array 208 can be operatively associated with the thermocouple 212.

In this respect the first pyrometer 210 can be connected to the controller 300, for example through the link 302, and can be configured to provide a first set of optical temperature measurements (T₁) to the controller 300. In addition, the second pyrometer 211 can be connected to the controller 300, for example through the link 302, and can be configured to provide a second set of optical temperature measurements (T₂) to the controller 300. Again, it should be noted, that the controller 300 may be connected to at least two pyrometers and the link 302 can be configured to provide (i.e., communicate) at least two sets of optical temperature measurements to the controller 300. Therefore, the embodiments of the disclosure can include a third, a fourth, and a fifth pyrometer, etc., providing a third (T₃), fourth (T₄), and fifth (T₅) set of optical temperature measurements to controller 300.

During the deposition of the material layer(s) 6 onto the substrate 4 the controller 300 may assign the first upper heater elements 262 to a first upper heating zone, and assign the second upper heater elements 264 to a second upper heating zone. The controller 300 can be configured to receive the first set of optical temperature measurements (T₁) from the first pyrometer 210, and also receive the second set of optical temperature measurement (T₂) from the second pyrometer 211. In some embodiments, a third set of tactile temperature measurements can be acquired from the thermocouple 212.

The controller 300 can then be configured to compare the first set of optical temperature measurements (T₁) to a predetermined first upper heating zone targets, and compare the second set of optical temperature measurements (T₂) to a predetermined second upper heating zone targets. In some embodiments, the controller 300 can be configured to further compare the tactile temperature measurement to a predetermined lower heating zone targets.

When any one of the comparisons is outside of a predetermined differential limit, the controller 300 may change power applied to first upper heater elements 262, and/or power applied to the second upper heater elements 264 based on the differential. For example, in some embodiments of the disclosure, throttling heat generated by the upper heater element array 206 may comprise, throttling heating of the substrate according to a temperature differential or a temperature gradient across an upper surface of the substrate 8 determined using the first set of optical temperature measurements (T₁) and the second set of optical temperature measurements (T₂).

In certain examples, each of the upper heater elements of the upper heater element array 206 may be distributed into a first upper heating zone 320 and second upper heating zones 330. For example, the first upper heating zone 320 may comprise a central heating zone and second heating zones 330 may comprise edge heating zones. For example, a plurality of first upper heater elements 262 (e.g., five (5) or more upper heater elements) of the upper heater element array 206 may be assigned to the first upper heating zone 320 and can be throttled using the first set of optical temperature measurements (T₁), and six (6) or more second upper heater elements 264 may be assigned to the second upper heating zones 330 and throttled using the second set of optical temperature measurements (T₂). In some embodiments of the disclosure, each of the lower heater elements may be assigned to a lower heating zone 340 and throttled using the a set of tactile temperature measurements provided by the thermocouple 212. In this respect each of lower heater elements included in the lower heater element array 108 may be assigned to a lower heating zone 340.

As will be appreciated by those of skill in the art in view of the present disclosure, in addition to the aforementioned advantages relating to limiting feedback associated with changes made to heat output from lower heater elements assigned to the lower heater element array 208, assigning the upper heater elements into the first upper heating zone 320 and the second upper heating zones 330 allows for controlling temperature variation between the center and the edge of the substrate 4 and particular the upper surface of the substrate 8. For example, a predetermined first upper heating zone target may be assigned to the first upper heating zone 320, and a predetermined second upper heating zone target may be assigned to the second upper heating zones 330, and a temperature difference between the center and the edge of the substrate 4 limited (or a non-zero differential maintained) during deposition of the material layer 6 onto the upper surface 8 of the substrate 4 can be accounted for and corrected by throttling power P₁ and P₂ (FIG. 3) to the first upper heater elements 262 (P₁) and second upper heater elements 264 (P₂). Driving a temperature differential across the substrate 4 by using the first set of optical temperature measurements (T₁) and the second set of optical temperature measurement (T₂) may, in certain examples, be employed in maintaining optimum materials deposition characteristics, including but not limited to, preserving a material layer profile, composition, thickness uniformity, doping concentration uniformity, and/or to prevent edge roll-up or edge roll-down, or other characteristic of the material layer(s) being deposited in the chamber arrangement 200.

Referring back to the exemplary method 100 (FIG. 1), once a substrate is seated within the chamber body (step 102), and the substrate surface temperature feedback control procedure (step 104) is engaged, the exemplary method 100 may proceed by, depositing a semiconductor stacked structure on a substrate by performing two or more sequences of a sequential deposition process (step 106). For example, each sequence of the sequential deposition process can comprise at least the process steps of; introducing a first precursor gas into the chamber body to epitaxially deposit a first layer comprising silicon and germanium on the substrate, subsequently introducing a transition gas into the chamber body to passivate an exposed surface of the first layer, and subsequently introducing a second precursor gas into the chamber body to epitaxially deposit a second layer comprising silicon over the first layer. It should be noted that in exemplary method 100 (FIG. 1) process step 106 is illustrated as being feedback to process step 104. This feedback step is illustrated to indicate that the feedback temperature control procedure for the upper surface of the substrate (as described herein above) is engaged throughout each of the process steps of the sequential deposition process 106.

In more detail, FIG. 4 illustrates in more detail the process step 106 (and the constituent sub-steps of process step 106) employed for the temperature controlled sequential deposition of a semiconductor stacked structure via feedback with the process step 104. Process step 104 has been described in detail herein above and is therefore described in brief herein below when relevant to the process step 106 (and the constituent sub-steps of process step 106).

The sequential deposition process 106 may commence with sub-step 402 which comprises, introducing a first precursor gas into the chamber body to epitaxially deposit a first layer comprising silicon and germanium on the substrate.

In more detail, sub-step 402 can include heating the substrate, and particularly the upper surface of the substrate, to a desired deposition temperature within the chamber body. In some embodiments of the disclosure, sub-step 402 includes heating the substrate to a temperature of less than 1100° C., or to a temperature of less than 850° C., or to a temperature of less than 700° C., or to a temperature of less than 650° C., or to a temperature of less than 600° C., or to a temperature of less than 550° C., or to a temperature of less than 500° C., or to a temperature of less than 450° C., or to a temperature of less than approximately 400° C., or even to a temperature of less than approximately 300° C. For example, in some embodiments of the disclosure, heating the substrate to a deposition temperature may comprise heating the substrate to a temperature between 400° ° C. and 1100° C., or between 400° C. and 700° C.

In addition to controlling the temperature of the substrate, the pressure within the chamber body may also be regulated. For example, in some embodiments of the disclosure, the pressure within the reaction chamber during sub-step 402 may be less than 760 Torr, or less than 350 Torr, or less than 100 Torr, or less than 50 Torr, or less than 25 Torr, or less than 10 Torr, or even less than 5 Torr. In some embodiments, the pressure in the chamber body may be between 5 Torr and 760 Torr, between 10 Torr and 200 Torr, or between 10 Torr and 100 Torr.

In some embodiments, the substrate temperature and the pressure within chamber body for sub-steps 402, 404, and 406 (of the sequential deposition process 106) can be substantially maintained throughout the entirety of the process. In alternative embodiments, the substrate temperature and pressure within the chamber body may be adjusted between the constituent sub-steps of the sequential deposition process depending on the needs of the materials being epitaxially deposited by the sequential deposition process 106.

The constituent sub-steps (e.g., the individual process steps 402, 404, and 406) of the sequential deposition process 106 (FIG. 4) can modify the environment within the chamber body. For example, the thermal environment within the chamber body can be altered by the introduction of precursor gases, reactants, and transition gases. The gases introduced into the chamber body can have different thermal conductivities as well as being at different initial temperatures to that already established within the chamber body. Therefore, the introduction of processes gases into the chamber body can alter the temperature within the chamber body, which can in turn, change the substrate temperature and particularly the temperature of the upper surface of the substrate upon which deposition is to be performed. Therefore, and as illustrated in FIG. 4, the feedback control procedure for regulating the temperature profile of the upper surface of the substrate (step 104), as previously described herein above, can be engaged continuously throughout the individual process steps (sub-steps 402, 404, and 406) to maintain a desired temperature of the upper surface of the substrate as different gases are introduced into the chamber body and environmental conditions within the chamber body vary.

The sequential deposition process 106 may continue with the sub-step 402 which comprises epitaxially depositing a first layer comprising silicon and germanium overlying a surface of a substrate and can include introducing a first precursor gas into the chamber body. In some embodiments, introducing the first precursor gas into the chamber body may comprise, introducing one or more silicon containing gases, one or more germanium containing gases, and one or more chlorine containing gases.

For example, a silicon precursor, a germanium precursor, and a chlorine containing gas, can be provided to a gas distribution assembly (not shown) at the injection end 226 (FIG. 2) of the reaction chamber assembly 200, e.g., through one or more gas injectors, such as multi-port injectors (MPIs), including a plurality of individual port injectors for providing a gas mixture into the reaction chamber. Various combinations of the precursors can be supplied to one or more of the individual port injectors to fine tune concentration profiles as desired. The silicon precursor, the germanium precursor, and the chlorine containing gas can be provided to the reaction chamber, such that gas phases of the precursors/reactants are provided into the chamber for an overlapping period. For example, both precursors/reactants can be provided to the reaction chamber for substantially the same period.

Exemplary silicon precursors include silanes and silicon halides. In some embodiments, the silicon halide compound can include, for example, a silicon halide having the general formula given as: SiₓW_{y}H₂, wherein “W” is a halide selected from the group consisting of Fluorine (F), Chlorine (Cl), Bromine (Br), and Iodine (I), “x” and “y” are integers greater than zero, and “z” is an integer greater than or equal to zero. In some embodiments, the silicon halide precursor may be selected from the group consisting of silicon fluorides (e.g., SiF₄), silicon chlorides (e.g., SiCl₄), silicon bromides (e.g., SiBr₄), and silicon iodides (e.g., Sil₄). In some embodiments, the silicon halide precursor may comprise silicon tetrachloride (SiCl₄). In some embodiments, the silicon halide precursor may comprise a silane, such as, for example, silane (SiH₄), disilane (Si₂H₆), trisilane (Si₃H₈), tetrasilane (Si₄H₁₀), or higher order silanes with the general empirical formula SiₓH(₂ₓ₊₂).

By way of examples, the silicon precursor can be or include one or more of silicon tetrachloride (SiCl₄), trichloro-silane (SiCl₃H), dichlorosilane (SiCl₂H₂), monochlorosilane (SiCIH₃), hexachlorodisilane (HCDS), octachlorotrisilane (OCTS), a silicon iodide, a silicon bromide; or an amino-based precursor, such as hexakis(ethylamino)disilane (AHEAD) and SiH[N(CH₃)₂]₃(3DMASi), a bis(dialkylamino)silane, such as BDEAS (bis(diethylamino)silane); a mono(alkylamino)silane, such as di-isopropylaminosilane; or an oxysilanes-based precursor, such as tetraethoxysilane Si(OC₂H₅)₄.

In some embodiments, the silicon precursor can include two or more precursors, such as a halogenated precursor (e.g., a silicon halide compound noted above) and a silane precursor. By way of example, the silicon precursor can include dichlorosilane and silane.

Exemplary germanium precursors can include germanes, such as germane (GeH₄), digermane (Ge₂H₆), trigermane (Ge₃H₈), or germylsilane (GeH₆Si), and halogen compounds, such as GeBr₄ or other suitable germanium-containing precursor. By way of examples, the germanium precursor can include one or more of germane and germanium tetrachloride (GeCl₄) or GeClₓH₄₋ₓ₋

Exemplary chlorine containing gases can include hydrochloric acid vapor (HCl), and chlorine gas (Cl₂).

Volumetric flow rates and flow ratios of the silicon precursors, the germanium precursors, and the chlorine containing gases can vary in accordance with the desired composition of the first layer. By way of example, a flowrate of a silicon precursor can be 10 sccm to 700 sccm, or 10 sccm to 400 sccm, or 10 sccm to 200 sccm; a flowrate of a germanium precursor can be 10 sccm to 990 sccm, 10 sccm to 220 sccm, or 10 sccm to 85 sccm; either of which flowrates can be with or without a carrier gas.

The first layer, such as, a silicon germanium (SiGe) layer, may form as a crystalline (e.g., monocrystalline) material overlying at least a portion of the surface of the substrate. Accordingly, at least a portion of the first layer may be monocrystalline and serve as a template for further epitaxial layers. In some cases, the entire first layer may be monocrystalline. In some cases, the first layer can form as non-monocrystalline material in some areas.

In some embodiments, the average layer thickness of the first layer comprising SiGe formed during sub-step 402 can be between greater than zero or 2 nm and 10 nm, between 2 nm and 20 nm, or between 2 nm and 100 nm.

The first layer comprising SiGe, can include about 70 to about 80 atomic percent (at-%), or about 70 to about 90 at-%, or about 70 to about 99 at-% silicon and/or about 1 to about 30 at-%, or about 5 to about 20 at-%, or about 15 to about 30 at-% or about 20 to about 30 at-% germanium. In some embodiments, the germanium content within the first layer may not be constant, but rather may can be varied, such that the germanium content (and/or other component) may have a graded composition within the first layer. In some embodiments, the germanium content (x) uniformity is less than 1%, or less than 0.5%, or less than 0.2%, or less than 0.1%, or between 0.1% and 1%.

Once the first layer (e.g., the first SiGe layer) has been deposited the sequential deposition process 106 may proceed with sub-step 404 by subsequently introducing a transition gas into the chamber body to passivate an exposed surface of the first layer. In some embodiments, prior to introducing the transition gas into the chamber body the flow of any germanium containing gases is stopped to remove or substantially remove any germanium containing gas from the chamber body and particular from the substrate. Therefore, in some embodiments, sub-step 404 may further comprise, stopping the flow of any germanium containing gas into the chamber body, and subsequently introducing the transition gas in the chamber body.

The transition gas can comprise one or more of, a silicon containing gas, a silicon halide containing gas, and a chlorine containing gas. For example, the transition gas can comprise, a silicon containing gas, and at least one of a silicon halide containing gas, and hydrochloric acid (HCl) vapor. In particular embodiments, the transition gas can comprise silane (SiH₄), and at least one of dichlorosilane (SiH₂Cl₂), and hydrochloric acid (HCl) vapor.

Volumetric flow rates and flow ratios of the components of the transition gas, such as, for example, silane (SiH₄), and at least one of dichlorosilane (SiH₂Cl₂), and hydrochloric acid (HCl) vapor can vary in accordance with the desired passivation of the exposed surface of the SiGe layer. The passivation of the exposed surfaces of the SiGe layer may be affected by a number of factors, including, but not limited to, the substrate temperature, the chemical composition of the transition gas, as well as the volumetric flow rates and flow ratios of the gas components of the transition gas.

The transition gas can be introduced into the chamber body after the deposition of a SiGe layer to mitigate or even prevent segregation of germanium into subsequently epitaxially deposited layers upon the SiGe layer. For example, the introduction of the transition gas can reduce the average thickness of an interface layer formed between the SiGe layer and a subsequently deposited silicon (Si) layer. In addition, the period of time that the transition gas flows into the chamber body and contacts the substrate, and particularly contacts the deposited SiGe layer can influence the quality of the transition region and hence the average interface layer thickness between the SiGe layer and a subsequent Si layer epitaxially deposited directly on the SiGe layer.

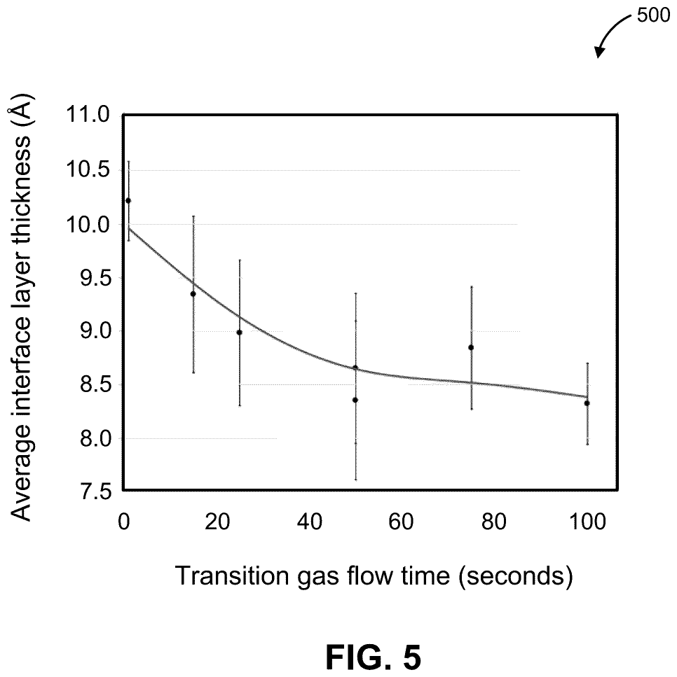

For example, FIG. 5 graphically illustrates exemplary data 500 demonstrating the relationship between the transition gas flow time and the corresponding average thickness of the interface layer formed between the SiGe layer and the overlaying Si layer, where the average interface layer thickness was determined by transmission electron microscopy (TEM)

As demonstrated by data 500 (FIG. 5), an increase in the transition gas flow time results in a corresponding decrease in the average interface layer thickness between a SiGe layer and a Si layer epitaxially deposited directly on the SiGe layer. For example, in some embodiments, the average interface layer thickness between a first layer (e.g., SiGe) and a second layer (e.g., Si) can be less than 10 Angstroms, or less than 9 Angstroms, or less than 8 Angstroms, or less than 7 Angstroms, or less than 6 Angstroms, or between 6 Angstroms and 10 Angstroms, for a transition gas flow time of less than 240 seconds, or less than 100 seconds, or less than 80 seconds, or less than 60 seconds, or less than 40 seconds, or less than 20 seconds, or less than 10 seconds, or less than 5 seconds, or less than 1 second, or between 1 second and 240 seconds.

In some embodiments of the disclosure, the average interface layer thickness (i.e., the interface layer between SiGe/Si) across the entire substrate (e.g., a 300 millimeter silicon substrate), or across a substantial majority of the substrate, can be less than 10 Angstroms, or less than 9 Angstroms, or less than 8 Angstroms, or less than 7 Angstroms, or less than 6 Angstroms, or less than 5 Angstroms, or less than 4 Angstroms, or less than 3 Angstroms, or less than 1 Angstrom, or equal to zero Angstroms, or between zero Angstroms and 10 Angstroms, for a transition gas flow time of less than 240 seconds, or less than 100 seconds, or less than 80 seconds, or less than 60 seconds, or less than 40 seconds, or less than 20 seconds, or less than 10 seconds, or less than 5 seconds, or less than 1 second, or between 1 second and 240 seconds. In some embodiments, the average interface layer thicknesses given above can be achieved over 100 percent (%) of a 300 millimeter substrate.

In some embodiments, the sub-step 404 (FIG. 4) comprising, introducing a transition gas into the chamber body to passivate an exposed surface of the first layer (SiGe) can further comprise, depositing a silicon (Si) capping layer directly over the first layer. For example, during flow of the transition gas into the chamber body, the gas components making up the transition gas can deposit a silicon (Si) capping layer directly over the exposed surface of the first layer, i.e., the SiGe layer. The deposition rate of the silicon (Si) capping layer can depend on the chemical composition of the transition gas, the flow period of the transition gas into the chamber body, and the temperature of the substrate, but can result in the deposition of a silicon (Si) capping layer directly over the SiGe layer at a deposition rate of less than 2.0 Angstroms per second, or less than 1.0 Angstroms per second, or less than, 0.5 Angstroms per second, or less than 0.4 Angstroms per second, less than 0.3 Angstroms per second, or less than 0.2 Angstroms per second, or less than 0.1 Angstroms per second, or between 0.1 and 2.0 Angstroms per second The deposition of a silicon (Si) capping layer directly over the underlying SiGe layer can further prevent segregation of germanium (Ge) from the SiGe layer into subsequently deposited layers deposited over the SiGe layer. In some embodiments of the disclosure, the silicon (Si) capping can have an average layer thickness of less than 6 Angstroms, or less than 5 Angstroms, or less than 4 Angstroms, or less than 3 Angstroms, or less than 2 Angstroms, or less than 1 Angstrom, or less than 0.5 Angstroms, or between 0.5 and 6 Angstroms.

The sequential deposition process 106 (FIG. 4) may proceed by, subsequently introducing a second precursor gas into the chamber body to epitaxially deposit a second layer comprising silicon over the first layer (sub-step 406). During sub-step 406, a second layer comprising silicon can be epitaxially deposited overlying the first layer (i.e., the SiGe layer) over at least a portion of the substrate. The second precursors employed for the epitaxial deposition of the second layer comprising silicon can be the same or similar to the silicon precursors described previously with reference to the deposition of the SiGe layer (sub-step 402). For example, the second layer comprising silicon (Si) may be epitaxially deposited over the SiGe layer employing one or more silicon precursors, including, but not limited to, silane (SiH₄), disilane (Si₂H₆), trisilane (Si₃H₈), tetrasilane (Si₄H₁₀), isopentasilane (Si₅H₁₂), or neopentasilane (Si₅H₁₂). In some embodiments, the silicon precursor may comprise a higher order silane precursor with the general empirical formula SiₓH(₂ₓ₊₂). In some embodiments, the silicon precursor gas may comprise dichlorosilane (DCS).

Sub-step 406 can be performed in the same chamber body used during sub-step 402 and 404. Alternatively, sub-step 406 can be performed in another chamber body, such as another chamber body in the same cluster tool as the chamber body used during sub-steps 402, and 404 or of another reactor system. The temperature and/or pressure for sub-step 406 can be the same or similar to the temperature and/or pressure described above in connection with sub-steps 402 and 406.

In some embodiments, the average layer thickness of the second layer (i.e., the silicon layer) epitaxially deposited during sub-step 406 can be between greater than zero or 2 nm and 4 nm, between 2 nm and 10 nm, between 2 nm and 20 nm, or between 2 nm and about 100 nm. In some embodiments, the silicon layer can have an thickness non-uniformity of less than 2 Angstroms, or less than 1 Angstrom, or less than 0.5 Angstroms, or between 0.5 Angstroms and 2 Angstroms.

In some embodiments of the disclosure, the sub-steps 402, 404, and 406, may collectively comprise a single (or unit) sequence of the sequential deposition cycle 106 (FIG. 4) and the methods of the present disclosure may further comprise performing two or more sequences of the sequential deposition process to deposit a semiconductor stacked structure.

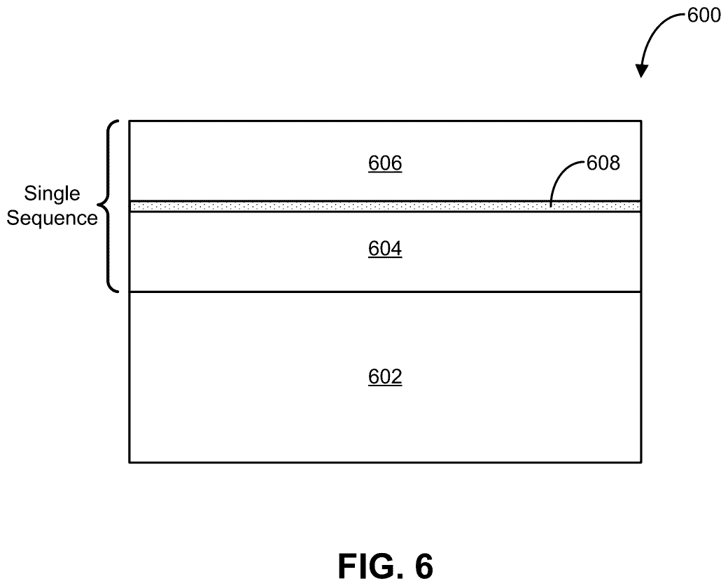

In more detail, a single sequence (sub-steps 402, 404, and 406) of the sequential deposition process 106 (FIG. 4) may be utilized to deposit a SiGe/Si layer structure (i.e., a SiGe/Si bilayer) over a substrate. For example, FIG. 6 illustrates the structure 600 deposited by performing a single (or first) sequence of the sequential deposition process 106. The structure 600 comprises, a substrate 602, a first layer comprising silicon germanium (SiGe) 604, and a second layer comprising silicon (Si) 606, with an intervening interface layer 608 disposed between the first layer (SiGe) 604, and the second layer (Si), the interface layer 608 having a minimized average layer thickness due to the embodiments of the present disclosure.

Therefore, in some embodiments, the sequential deposition process 106 (FIG. 4) can proceed by depositing a further number of SiGe/Si layer structures (i.e., SiGe/Si bilayers) over the substrate to form a semiconductor stacked structure. For example, the sequential deposition process 106 (FIG. 4) may proceed with a decision gate 408 which determines if a further sequence (402, 404, and 406) of the sequential deposition process 106 is repeated for depositing a further SiGe/Si layer structure on the substrate. The decision gate 408 can be dependent on the number SiGe/Si layer structures required for a particular device structure or device application. For example, if the decision is taken to perform a second sequence of the sequential deposition process 106, then the individual process sub-steps 402, 404, and 406 are repeated and a second SiGe/Si layer structure can be epitaxially deposited upon the first SiGe/Si layer.

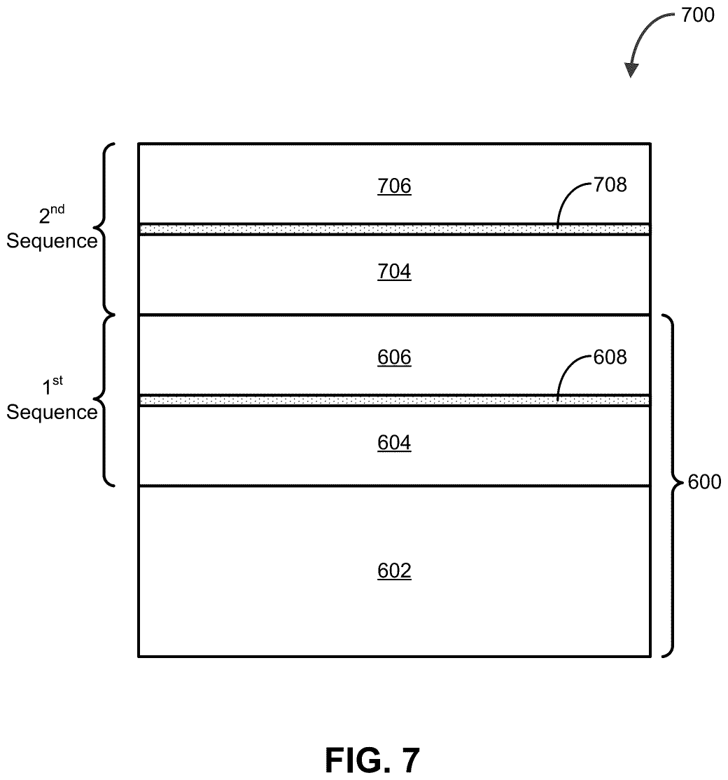

For example, FIG. 7 illustrates a semiconductor stacked structure 700 which comprises the structure 600 (FIG. 6) as deposited by performing a first sequence of the sequential deposition process (as described previously) with the addition of further semiconductor layers epitaxially deposited by performing a second sequence of the sequential deposition process 106. For example, performing the second sequence of the sequential deposition process 106 (sub-steps 402, 404, and 406) results in the deposition of a second silicon germanium (SiGe) layer 704 over the first silicon (Si) layer (606), as well as a second silicon (Si) layer 706 epitaxially deposited over the second silicon germanium (SiGe) layer, with an intervening second interface layer 708, disposed between the second silicon germanium (SiGe) layer 704, and the second silicon (Si) layer 706.

Therefore, the sequential deposition process 106 can be repeated two or more (or any number) of times to deposit a semiconductor stacked structure comprising two or more (or any number) of SiGe/Si layers epitaxially deposited one on top of one another. Once the desired number of SiGe/Si layers have been epitaxially deposited to form a semiconductor stacked structure with the desired structure, the sequential deposition process 106 can be terminated as illustrated in FIG. 4 by sub-step 410 which comprises, ending the sequential deposition process. The conclusion of the sequential deposition process 106 can also result in the end of the overall exemplary method 100, as illustrated by the end of process step 108 (FIG. 0.1).

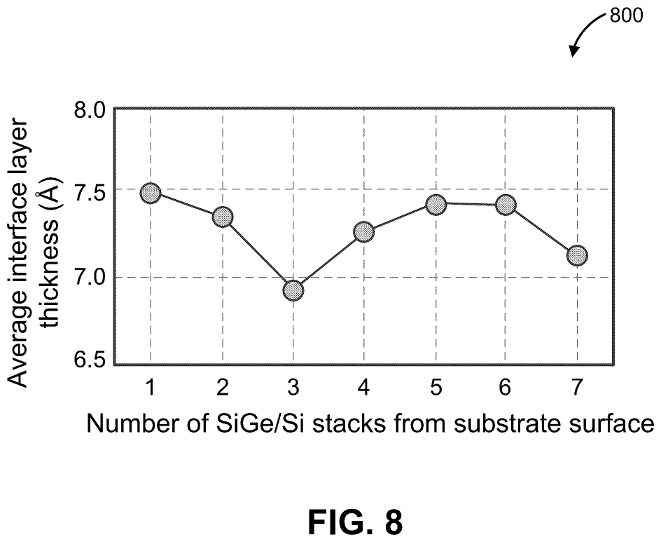

To further illustrate the advantages of the embodiments of the present disclosure FIG. 8 graphically illustrates exemplary data 800 demonstrating high quality, interface layers with low average thicknesses obtained across an entire SiGe/Si semiconductor stacked structure. In this non-limiting example, the semiconductor stacked structure includes seven (7) SiGe/Si layer structures epitaxially deposited one on top of one another according to the methods outlined herein. For example, the seven (7) SiGe/Si layer structures are epitaxially deposited on the surface of substrate by performing seven (7) sequences of the sequential deposition process 106 (FIG. 4) whilst employing continuous feedback temperature control over the surface temperature of the substrate as described herein above. Examination of the data 800 in FIG. 8 demonstrates that the average interface layer thickness throughout the entire semiconductor stacked structure is less than 7.5 Angstroms. The data 800 in FIG. 8 also further illustrates that the average interface layer thickness throughout the entire semiconductor stacked structure ranges from as low as approximately 6.9 Angstroms to approximately 7.5 Angstroms.

Therefore, the methods of the present disclosure can enable the epitaxial deposition of semiconductor stacked structures which comprise multiple interface layers extending throughout the entire height of the semiconductor stacked structure having an average interface layer thickness of less than 20 Angstroms, or less than 10 Angstroms, or less than 7.5 Angstroms, or less than 7.0 Angstroms, or less than 6.5 Angstroms, or less than 6.0 Angstroms, or less than 5.0 Angstroms, or less than 4 Angstroms, or less than 2 Angstroms, or equal to zero Angstroms, or between zero Angstroms and 20 Angstroms. In some embodiments, a semiconductor stacked structure may comprise greater than 2 SiGe/Si interfaces, or greater than 4 SiGe/Si interfaces, or greater than 6 SiGe/Si interfaces, or greater than 8 SiGe/Si interfaces, or even greater than 10 SiGe/Si interfaces, with an average interface layer thickness throughout the entire semiconductor stacked structure of less than 20 Angstroms, or less than 10 Angstroms, or less than 7.5 Angstroms, or less than 7.0 Angstroms, or less than 6.5 Angstroms, or less than 6.0 Angstroms, or less than 5.0 Angstroms, or less than 4 Angstroms, or less than 2 Angstroms, or equal to zero Angstroms, or between zero Angstroms and 20 Angstroms.

It should be noted that the average interface layer thickness values given above are highly depended on the characterization methods employed in determining said thicknesses. For example, the data provided herein is determined utilizing 16-84% of a scanning tunneling electron microscopy (STEM) intensity interval to calculate the average interface layer thickness.

Therefore, the embodiments of the disclosure may include semiconductor structures, comprises, a substrate, and two or more bilayers disposed directly one on top of another to form a semiconductor stacked structure. In some embodiments, a single bilayer may comprise, a silicon germanium (Si₁₋ₓGeₓ) layer, a silicon (Si) layer disposed over the silicon germanium (Si₁₋ₓGeₓ) layer, and an interface layer disposed directly between the silicon germanium (Si₁₋ₓGeₓ) layer and the silicon (Si) layer. In some embodiments, each interface layer within the semiconductor stacked structure can have an average thickness of less than 20 Angstroms, or less than 10 Angstroms, or less than 9 Angstroms, or less than 8 Angstroms, or less than 7 Angstroms, or less than 6 Angstroms, or less than 5 Angstroms, or less than 4 Angstroms, or less than 2 Angstroms, or equal to zero Angstroms, or between zero Angstroms and 20 Angstroms. In addition, each silicon (Si) layer within the semiconductor stacked structure can have an thickness non-uniformity of less than 2 Angstroms, or less than 1 Angstrom, or less than 0.5 Angstroms, or between 0.5 Angstroms and 2 Angstroms. In addition, each silicon germanium (Si₁₋ₓGeₓ) layer within the semiconductor stacked structure can have an germanium content (x) non-uniformity of less than 1%, or less than 0.5%, or less than 0.2%, or than 0.1%, or between 0.1% and 1%.

The semiconductor stacked structures formed by the methods disclosed herein may be employed in the formation of next generation three-dimensional devices, including but not limited to, gate-all-around (GAA) devices, nanosheet devices, forksheet devices, and complementary FET (CFET) type devices. For example, during the fabrication of such three-dimensional devices, the semiconductor stacked structures of the present disclosure which are composed of alternating layers of silicon germanium (SiGe layers) and silicon (Si layers) can be processed to remove the SiGe layers whilst maintaining the silicon layers. The remaining silicon layers can then go through further fabricated processes to form the next generation channel regions in the form of sheets, nanowires, etc. The sharp, thin SiGe/Si interface layers realized by the methods disclosed within can enable the formation of such next generation silicon channel regions with a greater degree of precision than previously achievable.

Examples of next generation three-dimensional devices that are better enabled as a result of the methods disclosed herein are briefly described below.

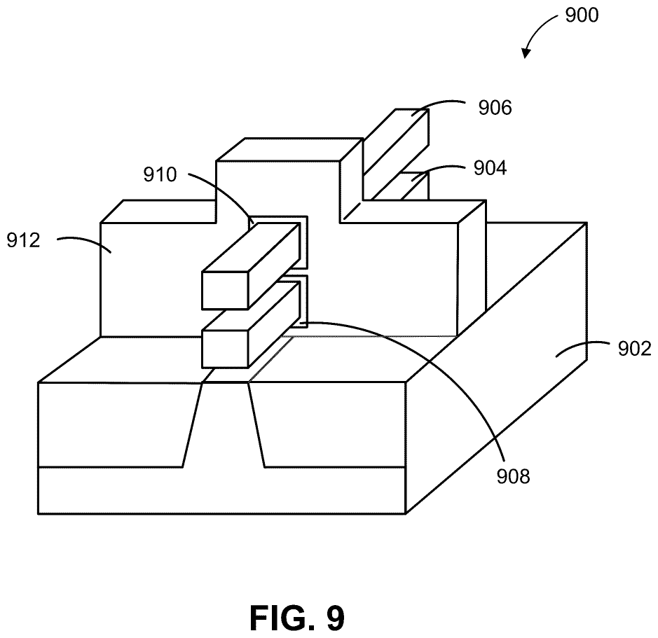

FIG. 9 illustrates a simplified schematic diagram of an exemplary gate-all-around device structure 900 and comprises a substrate 902, two silicon nanowire channel regions 904, and 906, dielectric material 908, 910, and a conducting material 912. The silicon nanowire channel regions 904 and 906 can be fabricated from the semiconductor stacked structures formed by the epitaxial deposition methods as described herein.

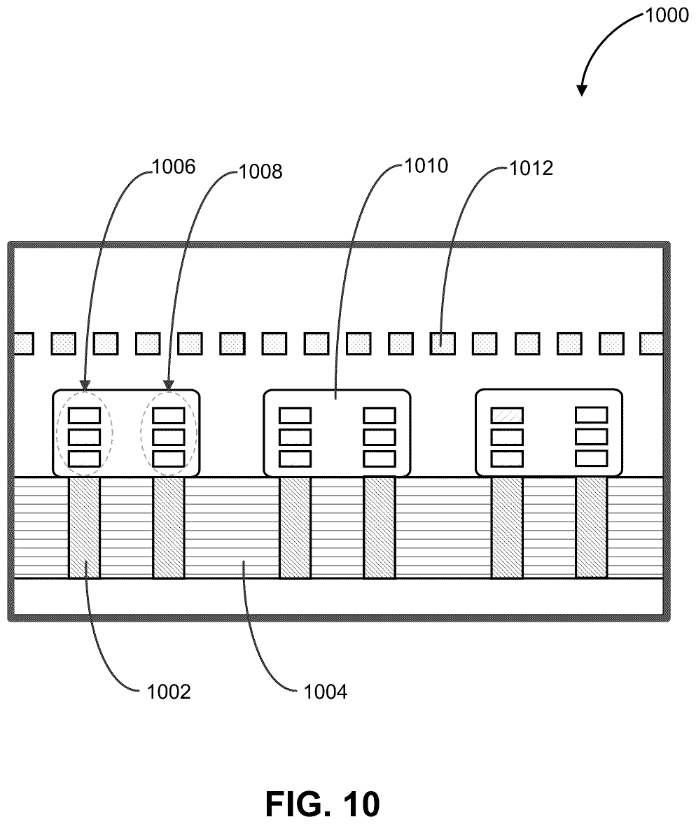

FIG. 10 illustrates a simplified schematic diagram of an exemplary nanosheet device structure 1000 which comprises, silicon regions 1002, and dielectric region 1004. The regions denoted as 1006 and 1008 correspond to p-type and n-type nanosheets (three sheets each respectively in this example) that can be fabricated from the semiconductor stacked structures formed by the epitaxial deposition methods described herein. The exemplary nanosheet device structure 1000 also includes the gate electrode 1010 and the electrical contacts 1012.

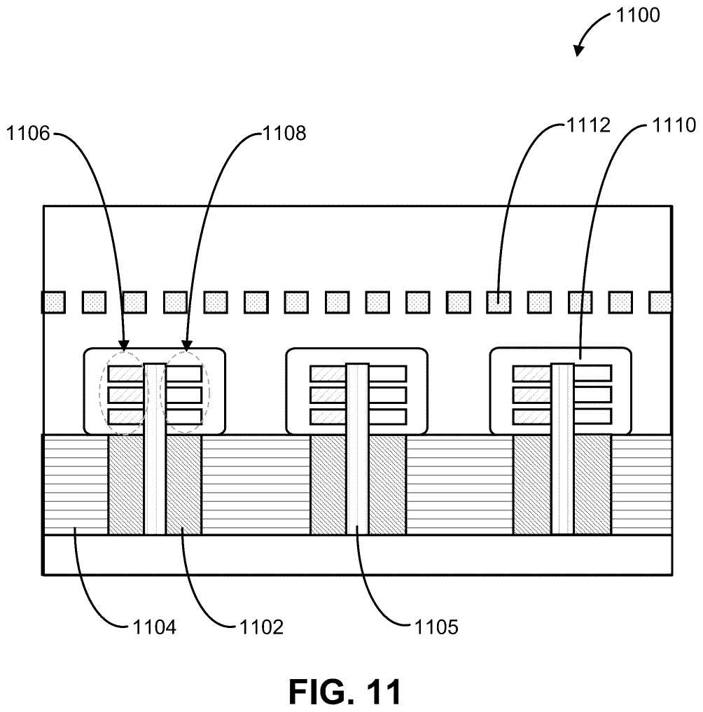

FIG. 11 illustrates a simplified schematic diagram of an exemplary forksheet device structure 1100 and comprises silicon regions 1102, dielectric regions 1104, and dielectric walls 1105. The regions denoted as 1106 and 1108 correspond to p-type and n-type silicon nano-channel regions that can be fabricated from the semiconductor stacked structures formed by the epitaxial deposition methods described herein. The exemplary forksheet device structure 1100 also includes the gate electrode 1110 and the electrical contacts 1012.

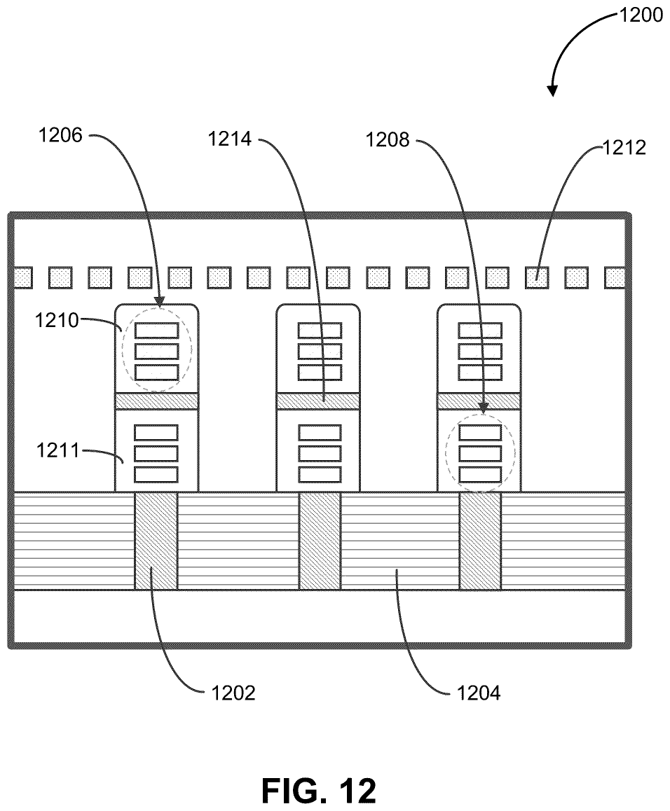

FIG. 12 illustrates a simplified schematic diagram of an exemplary complementary FET (CFET) device structure 1200 and comprises silicon regions 1202, and dielectric regions 1204. The regions denoted as 1206 and 1208 correspond to p-type and n-type silicon nano-channel regions that can be fabricated from the semiconductor stacked structures formed by the epitaxial deposition methods described herein. The exemplary CFET device structure 1200 also includes the upper and lower gate electrodes (1210 and 1211 respectively), a dielectric region 1214 disposed between the upper and lower gate electrodes and electrical contacts 1212.

Therefore, the embodiments of the present disclosure also include partially fabricated semiconductor device structures, wherein the partially fabricated device structures may comprise a partially fabricated gate-all-around device structure, a nanosheet device structure, a forksheet device structure, and a complementary FET (CFET) device structure. For example, the semiconductor stacked structures of the present disclosure including multiple stacks of SiGe/Si bilayers one on top of one another can comprise at least a portion of a partially fabricated gate-all-around device structure, a partially fabricated nanosheet device structure, a partially fabricated forksheet device structure, and a complementary FET (CFET) device structure

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A method for forming a semiconductor structure, the method comprising:
seating a substrate within a chamber body;
regulating a temperature profile across an upper surface of the substrate during each individual process step of a sequential deposition process by employing a feedback control procedure comprising;
acquiring at least two independent sets of optical temperature measurements from at least two separate areas on the upper surface of the substrate; and
throttling heating of the substrate according to a temperature differential or a temperature gradient across the upper surface of the substrate as determined by the at least two independent sets of optical temperature measurements; and
depositing a semiconductor stacked structure on the substrate by performing two or more sequences of a sequential deposition process, wherein each sequence of the sequential deposition process comprises at least process steps of:
introducing a first precursor gas into the chamber body to epitaxially deposit a first layer comprising silicon and germanium on the substrate;
subsequently introducing a transition gas into the chamber body to passivate an exposed surface of the first layer; and
subsequently introducing a second precursor gas into the chamber body to epitaxially deposit a second layer comprising silicon over the first layer.

2. The method of claim 1, wherein throttling the heating of the substrate further comprising, regulating power supplied to a upper heater element array disposed above the chamber body based on the at least two independent sets of optical temperature measurements.

3. The method of claim 2, wherein the at least two independent sets of optical temperature measurements comprise a first set of optical temperature measurements (T₁) acquired from a first acquisition area of the upper surface of the substrate by a first pyrometer supported above the upper heater element array, and a second set of optical temperature measurements (T₂) acquired from a second acquisition area of the upper surface of the substrate by a second pyrometer supported above the upper heater element array, wherein the first acquisition area and the second acquisition area are separated from one another.

4. The method of claim 3, wherein the first pyrometer is arranged along a first optical axis and the second pyrometer is arranged along a second optical axis, the second optical axis being radially outward of the first optical axis.

5. The method of claim 1, wherein the first layer comprises a silicon germanium (Si₁₋ₓGeₓ) layer, wherein the germanium content (x) is greater than zero and less than 0.5, and the germanium content (x) non-uniformity is less than 0.2%.

6. The method of claim 1, wherein introducing a transition gas into the chamber body further comprises, stopping flow of any germanium containing gas into the chamber body, and subsequently introducing the transition gas into the chamber body, wherein the transition gas comprises a silicon containing gas, and at least one of a silicon halide containing gas, and hydrochloric acid (HCl) vapor.

7. The method of claim 1, wherein introducing the transition gas into the chamber body further comprises, depositing a silicon capping layer directly on the first layer.

8. The method of claim 1, wherein an interface layer is disposed between the first layer and the second layer, the interface layer having an average thickness of less than 10 Angstroms.

9. A semiconductor stacked structure comprising two or more bilayers, each bilayer comprising a silicon germanium (Si₁₋ₓGeₓ) layer, an overlaying silicon (Si) layer, and an interface layer disposed directly between the silicon germanium (Si₁₋ₓGeₓ) layer and silicon (Si) layer, formed by claim 1.

10. A method for forming a semiconductor stacked structure on a surface of a substrate, the method comprising:
seating a substrate on a substrate support disposed in a chamber body, the chamber body having an upper wall and a lower wall;
heating the substrate to a deposition temperature employing an upper heater element array supported above the upper wall of the chamber body and a lower heater element array supported below the lower wall of the chamber body;
providing a controller in communication with at least the upper heater element array, wherein the controller throttles power to at least the upper heater element array according to a set of optical temperature measurements communicated to the controller from at least a first pyrometer and a second pyrometer, the first pyrometer and the second pyrometer being supported above the upper heater element array and being optically coupled to the substrate surface over at least a first acquisition area and a second acquisition area, wherein the second acquisition area is radially distal from the first acquisition area; and
depositing two or more silicon germanium (Si₁₋ₓGeₓ)/silicon (Si) bilayers on the substrate by a sequential deposition process, wherein a unit sequence of the sequential deposition process comprises at least process steps of:
epitaxially deposit a silicon germanium (Si₁₋ₓGeₓ) layer over the substrate;
introducing a transition gas comprising a chlorine containing gas into the chamber body for set time period;
epitaxially depositing a silicon (Si) layer over the silicon germanium (Si₁₋ₓGeₓ) layer; and
forming an interface layer disposed between the silicon germanium (Si₁₋ₓGeₓ) layer and the silicon (Si) layer, wherein the interface layer has an average thickness of less than 10 Angstroms.

11. The method of claim 10, wherein introducing the transition gas further comprises, stopping flow of any germanium containing precursor into the chamber body prior to introducing the transition gas, the transition gas comprising, silane (SiH₄), and at least one of dichlorosilane (DCS), and hydrochloric acid (HCl) vapor.

12. The method of claim 10, wherein introducing the transition gas further comprises, reducing the thickness of the interface layer with increasing flow time of the transition gas.

13. The method of claim 10, wherein the transition gas is introduced into the chamber body for a time period of less than 100 seconds.

14. The method of claim 10, wherein the interface layer further comprises a silicon capping (Si) layer deposited directly on the surface of the silicon germanium (Si₁₋ₓGeₓ) layer, wherein the silicon (Si) capping layer prevents segregation of germanium (Ge) from the silicon germanium (Si₁₋ₓGeₓ) layer into an adjacent silicon (Si) layer.

15. The method of claim 10, wherein the upper wall of the chamber body extends longitudinally between an injection end and a longitudinally opposite exhaust end, and the lower wall is below and parallel relative to the upper wall.

16. The method of claim 10, wherein the chamber body comprises an arcuate, or dome-like shape.

17. A semiconductor structure comprising:
a substrate;
two or more bilayers disposed directly one on top of one another to form a semiconductor stacked structure, wherein a single bilayer comprises;
a silicon germanium (Si₁₋ₓGeₓ) layer;
a silicon (Si) layer disposed over the silicon germanium (Si₁₋ₓGeₓ) layer; and
an interface layer disposed directly between silicon germanium (Si₁₋ₓGeₓ) layer and the silicon (Si) layer,
wherein each interface layer within the semiconductor stacked structure has an average layer thickness of less than 10 Angstroms.

18. The structure of claim 17, wherein each silicon germanium (Si₁₋ₓGeₓ) layer within the semiconductor stacked structure has a germanium content (x) greater than zero and less than 0.5 and a germanium content (x) non-uniformity of less than 0.2%.

19. The structure of claim 17, wherein each silicon layer within the semiconductor stacked structure has a thickness non-uniformity of less than 1 Angstroms.

20. A partially fabricated semiconductor device structure comprising the structure of claim 17, wherein the partially fabricated semiconductor device structure may comprise a partially fabricated gate-all-around (GAA) transistor device structure, a partially fabricated nanosheet device structure, a partially fabricated forksheet device structure, and a partially fabricated complementary FET (CFET) device structure.
